(19) United States
(12) Patent Application Publication
(10) Pub. No.: US 2026/0098134 A1
(43) Pub. Date: Apr. 9, 2026

(54) RESIN COMPOSITION, FILM WITH RESIN, PREPREG, METAL FOIL WITH RESIN, METAL-CLAD LAMINATE, AND PRINTED WIRING BOARD

(71) Applicant: Panasonic Intellectual Property Management Co., Ltd., Osaka (JP)

(72) Inventors: Yasunari TOMITA, Osaka (JP); Akihiro YAMAUCHI, Osaka (JP); Nobuo SHIBATA, Toyama (JP)

(73) Assignee: Panasonic Intellectual Property Management Co., Ltd., Osaka (JP)

(21) Appl. No.: 19/144,111

(22) PCT Filed: Dec. 20, 2023
(86) PCT No.: PCT/JP2023/045739

§ 371 Date: Jun. 27, 2025

(30) Foreign Application Priority Data
Dec. 27, 2022 (JP) 2022-210791

(51) Int. Cl. C08J 5/24; C08K 3/22; C08K 3/28; C08L 63/00; H05K 1/03

(52) U.S. Cl. CPC C08J 5/249; C08K 3/22; C08K 3/28; C08L 63/00; H05K 1/0366; H05K 1/0373; C08J 2363/00; C08J 2471/00; C08K 2003/222; C08K 2003/2227; C08K 2003/282; C08K 2201/005; C08K 2201/014; C08L 2203/20; H05K 2201/0209

(57) ABSTRACT

A resin composition contains an epoxy resin (A), a phenolic resin (B), a flow adjuster (C), and an inorganic filler (D). The flow adjuster (C) includes a polyether ester flow adjuster (C1) including no phosphorus atoms. The inorganic filler (D) includes at least one filler selected from the group consisting of a magnesium oxide filler, an aluminum nitride filler, and an aluminum oxide filler. The content of the inorganic filler (D) is equal to or greater than 84% by mass and equal to or less than 97% by mass with respect to the entire mass of the resin composition. The inorganic filler (D) has, in a volume-based particle size distribution measured by a laser diffraction and scattering method, at least two peaks within a range in which a particle size is equal to or greater than 0.05 μm and equal to or less than 25 μm.

### TECHNICAL FIELD

The present disclosure generally relates to a resin composition, a film with resin, a prepreg, a sheet of metal foil with resin, a metal-clad laminate, and a printed wiring board. More particularly, the present disclosure relates to a resin composition containing an epoxy resin, a film with resin, a prepreg, a sheet of metal foil with resin, a metal-clad laminate, and a printed wiring board.

### BACKGROUND ART

Patent Literature 1 discloses an epoxy resin composition for use in thermally conductive materials. The epoxy resin composition for use in thermally conductive materials contains an epoxy resin, a curing agent or a curing accelerator, and an inorganic filler (thermally conductive filler). The epoxy resin composition is characterized in that the epoxy resin has a triphenylene skeleton.

To increase the thermal conductivity, the resin composition needs to contain the filler at a high concentration. Nevertheless, as the concentration of the filler is increased, the flowability of the resin composition tends to decrease accordingly, thus generating the need to lower the viscosity of the resin composition as well. However, if the viscosity of the resin composition were too low, then the resin composition would flow so easily that it would be difficult to control the thickness of an insulating layer made of the resin composition. Consequently, there has been an increasing demand for developing a technique for increasing the thermal conductivity of the insulating layer while keeping its thickness as uniform as possible.

### CITATION LIST

### Patent Literature

Patent Literature 1: JP 2017-008153 A

### SUMMARY OF INVENTION

An object of the present disclosure is to provide a resin composition contributing to forming an insulating layer with a high thermal conductivity and a uniform thickness, a film with resin, a prepreg, a sheet of metal foil with resin, a metal-clad laminate, and a printed wiring board.

A resin composition according to an aspect of the present disclosure contains an epoxy resin (A), a phenolic resin (B), a flow adjuster (C), and an inorganic filler (D). The flow adjuster (C) includes a polyether ester flow adjuster (C1) including no phosphorus atoms. The inorganic filler (D) includes at least one filler selected from the group consisting of a magnesium oxide filler, an aluminum nitride filler, and an aluminum oxide filler. The content of the inorganic filler (D) is equal to or greater than 84% by mass and equal to or less than 97% by mass with respect to the entire mass of the resin composition. The inorganic filler (D) has, in a volume-based particle size distribution measured by a laser diffraction and scattering method, at least two peaks within a range in which a particle size is equal to or greater than 0.05 μm and equal to or less than 25 μm.

A film with resin according to another aspect of the present disclosure includes: a resin layer including either the resin composition described above or a semi-cured product of the resin composition; and a supporting film supporting the resin layer.

A prepreg according to another aspect of the present disclosure includes: a resin layer including either the resin composition described above or a semi-cured product of the resin composition; and a fibrous base member impregnated with the resin composition.

A sheet of metal foil with resin according to still another aspect of the present disclosure includes: a resin layer including either the resin composition described above or a semi-cured product of the resin composition; and a sheet of metal foil bonded to the resin layer.

A metal-clad laminate according to yet another aspect of the present disclosure includes: an insulating layer including a cured product of the resin composition described above; and a metal layer bonded to the insulating layer.

Another metal-clad laminate according to yet another aspect of the present disclosure includes: an insulating layer including a cured product of the prepreg described above; and a metal layer bonded to the insulating layer.

A printed wiring board according to yet another aspect of the present disclosure includes: an insulating layer including a cured product of the resin composition described above; and a conductor layer bonded to the insulating layer.

Another printed wiring board according to yet another aspect of the present disclosure includes: an insulating layer including a cured product of the prepreg described above; and a conductor layer bonded to the insulating layer.

### BRIEF DESCRIPTION OF DRAWINGS

FIG. 1A is a schematic cross-sectional view illustrating a film with resin (and with no protective film) according to an exemplary embodiment of the present disclosure; and FIG. 1B is a schematic cross-sectional view illustrating a film with resin (and with a protective film) according to the exemplary embodiment of the present disclosure;

FIG. 2 is a schematic cross-sectional view illustrating a prepreg according to the exemplary embodiment of the present disclosure;

FIG. 3 is a schematic cross-sectional view illustrating a sheet of metal foil with resin according to the exemplary embodiment of the present disclosure;

FIG. 4A is a schematic cross-sectional view illustrating a metal-clad laminate (with no fibrous base members) according to the exemplary embodiment of the present disclosure; and FIG. 4B is a schematic cross-sectional view illustrating a metal-clad laminate (with a fibrous base member) according to the exemplary embodiment of the present disclosure;

FIG. 5 is a schematic cross-sectional view illustrating a printed wiring board according to the exemplary embodiment of the present disclosure.

FIG. 6A is a schematic cross-sectional view illustrating a printed wiring board under test (which has not been subjected to etching yet); and FIG. 6B is a schematic cross-sectional view illustrating a printed wiring board under test (which has been subjected to etching);

FIG. 7A is a schematic plan view illustrating a printed wiring board under test; and FIG. 7B is a schematic plan view illustrating a dummy pattern; and

FIG. 8 is a schematic plan view indicating points where the thickness of the printed wiring board under test is measured.

### DESCRIPTION OF EMBODIMENTS

### 1. Overview

Patent Literature 1 teaches, in paragraph [0058], that if the content of the thermally conductive filler were less than 40% by mass, then the epoxy resin composition for use in thermally conductive materials would not have sufficient thermal conductivity. On the other hand, Patent Literature 1 also teaches that if the content of the thermally conductive filler were greater than 95% by mass, then the epoxy resin composition for use in thermally conductive materials would have so high viscosity as to cause a decrease in applicability and workability.

As can be seen, to increase the thermal conductivity, the resin composition needs to contain the filler at a high concentration. Nevertheless, as the concentration of the filler is increased, the flowability of the resin composition tends to decrease accordingly, thus generating the need to lower the viscosity of the resin composition as well.

However, if the viscosity of the resin composition were too low, then the resin composition would flow so easily that it would be difficult to control the thickness of an insulating layer made of the resin composition. Patent Literature 1 cites, as intended use of the epoxy resin composition for use in thermally conductive materials, a material for an interlevel dielectric film for buildup boards and a material for an adhesive film for buildup boards (see, for example, paragraph [0022] of Patent Literature 1). If multiple insulating layers, each having a non-uniform thickness, were stacked one on top of another, then layers having non-uniform thicknesses would be compiled one on top of another to possibly make the thickness of the multilayer printed wiring board significantly non-uniform.

Thus, the present inventors carried out extensive research to increase the thermal conductivity of the insulating layer while keeping its thickness as uniform as possible. As a result, the present inventors successfully developed a resin composition contributing to forming an insulating layer with a uniform thickness while achieving a high thermal conductivity. Specifically, the resin composition according to this embodiment contains an epoxy resin (A), a phenolic resin (B), a flow adjuster (C), and an inorganic filler (D).

In this embodiment, the flow adjuster (C) includes a polyether ester flow adjuster (C1) including no phosphorus atoms. The polyether ester flow adjuster (C1) including no phosphorus atoms mainly contributes to making the thickness of the insulating layer 1 uniform.

On the other hand, the inorganic filler (D) includes at least one filler selected from the group consisting of a magnesium oxide filler, an aluminum nitride filler, and an aluminum oxide filler. The content of the inorganic filler (D) is equal to or greater than 84% by mass and equal to or less than 97% by mass with respect to the entire mass of the resin composition. The inorganic filler (D) has, in a volume-based particle size distribution measured by a laser diffraction and scattering method, at least two peaks within a range in which the particle size is equal to or greater than 0.05 μm and equal to or less than 25 μm. The inorganic filler (D) mainly contributes to the thermal conductivity of the insulating layer 1.

The present inventors discovered that if the resin composition contained the epoxy resin (A) and the phenolic resin (B) as described above, then the polyether ester flow adjuster (C1) including no phosphorus atoms achieved a particularly significant effect.

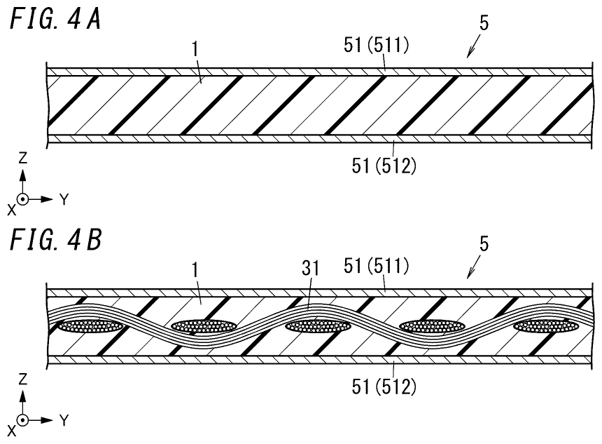

Thus, this embodiment contributes to forming an insulating layer having a high thermal conductivity and a uniform thickness. The insulating layer 1 is a layer with electrical insulation properties and includes a cured product of the resin composition (refer to FIGS. 4A-6B).

### 2. Details

A resin composition according to this embodiment will now be described. After that, a film 2 with resin, a prepreg 3, a sheet of metal foil 4 with resin, a metal-clad laminate 5, and a printed wiring board 6 according to this embodiment will be described with reference to the accompanying drawings. The drawings to be referred to in the following description of embodiments are all schematic representations. Thus, the ratio of the dimensions (including thicknesses) of respective constituent elements illustrated on the drawings does not always reflect their actual dimensional ratio. Note that the arrows indicating respective directions on the drawings should not be construed as defining the directions in which the film 2 with resin and other embodiments of the present disclosure are supposed to be used but are shown there to make the following description easily understandable and are all insubstantial ones. Also note that the X-, Y-, and Z-axes cross each other at right angles. In the following description, when something is viewed along the Z-axis, the phrase “when viewed in an XY plane” will be used.

### (1) Resin Composition

A resin composition according to this embodiment includes an epoxy resin (A), a phenolic resin (B), a flow adjuster (C), and an inorganic filler (D). Optionally, the resin composition may further contain other additional components as well. Examples of other additional components include, without limitation, catalysts, flame retardants, coupling agents, dispersants, metal deactivators, and ion scavengers. The respective components will be sequentially described one by one.

### <Epoxy Resin (A)>

The epoxy resin (A) has the property of curing when heated. Thus, the epoxy resin (A) may impart thermosetting properties to the resin composition. The epoxy resin (A) is a compound having at least one epoxy group per molecule. The epoxy resin (A) preferably has two or more epoxy groups per molecule.

Examples of the epoxy resin (A) include, without limitation, trisphenolmethane epoxy resins, naphthalene epoxy resins, biphenyl-aralkyl epoxy resins, biphenyl epoxy resins, and dicyclopentadiene epoxy resins.

Among other things, the trisphenolmethane epoxy resin is particularly preferred. The trisphenolmethane epoxy resin has three epoxy groups each having a phenylmethane skeleton per molecule. As can be seen, the trisphenolmethane epoxy resin has so high a functional group (epoxy group) density as to raise the glass transition temperature (Tg) of the cured product of the resin composition.

### <Phenolic Resin (B)>

The phenolic resin (B) is a prepolymer which may react with the epoxy resin (A). The phenolic resin (B) is a condensation reaction product of a phenol and an aldehyde.

Examples of phenolic resins (B) include, without limitation, biphenyl-aralkyl phenolic resins, phenyl-aralkyl phenolic resins, novolac phenolic resins, cresol-novolac phenolic resins, bisphenol A novolac phenolic resins, naphthalene phenolic resins, tetrakis-phenol phenolic resins, and phosphorus modified phenolic resin.

Among other things, the biphenyl-aralkyl phenolic resin is particularly preferred. The biphenyl-aralkyl phenolic resin may impart flame retardance, heat resistance, and adhesiveness to a cured product of the resin composition.

The equivalent ratio of the phenolic resin (B) to the epoxy resin (A) is preferably equal to or greater than 0.7 and equal to or less than 1.3, and more preferably equal to or greater than 0.8 and equal to or less than 1.0. Setting the equivalent ratio at a value equal to or greater than 0.7 reduces the chances of causing a decrease in glass transition temperature (Tg) and thereby reduces the chances of making the resin composition cured insufficiently. On the other hand, setting the equivalent ratio at a value equal to or less than 1.3 reduces an increase in polar groups such as a hydroxy group, thus reducing the chances of leaving smear when boring a hole through the insulating layer 1, for example.

### <Flow Adjuster (C)>

The flow adjuster (C) is a component which may adjust the degree of flowability of the resin composition being molded. The flow adjuster (C) includes a polyether ester flow adjuster (C1) including no phosphorus atoms. The polyether ester flow adjuster (C1) including no phosphorus atoms is effectively applicable to a resin system including, in combination, the epoxy resin (A) and the phenolic resin (B), in particular. That is to say, even if such a resin system includes the inorganic filler (D) at a high concentration, the polyether ester flow adjuster (C1) including no phosphorus atoms may impart moderate flowability to the resin composition being molded.

It is preferable that the flow adjuster (C) be liquid at 25° C. and non-ionic. The flow adjuster (C) in a liquid form at 25° C. increases the flexibility of a film material (such as the film 2 with resin, the prepreg 3, and the sheet of metal foil 4 with resin) and makes the film material less easily crackable, thus improving the handleability of the film material. In addition, the non-ionic flow adjuster (C) is not ionized and has no electric charges, thus ensuring insulation reliability for the insulating layer 1.

It is preferable that the polyether ester flow adjuster (C1) including no phosphorus atoms have, in a single molecule, a plurality of ether structures, a plurality of ester structures, and a plurality of carboxy groups. Such a polyether ester flow adjuster (C1) including no phosphorus atoms may be prepared by, for example, allowing a polyol having two to six hydroxyl groups and a carboxy group introduced substance to react with each other such that the molar ratio of the hydroxyl group to the carboxy group introduced substance falls within the range from 3:1 to 1:1. The polyether ester flow adjuster (C1) including no phosphorus atoms prepared in this manner may reduce the chances of the viscosity of the resin composition increasing too much or decreasing too much while the resin composition is being molded. This may make the thickness of the insulating layer 1 even more uniform.

The content of the flow adjuster (C) is preferably equal to or greater than 0.005 parts by mass and equal to or less than 0.5 parts by mass, more preferably equal to or greater than 0.008 parts by mass and equal to or less than 0.4 parts by mass, and even more preferably equal to or greater than 0.01 parts by mass and equal to or less than 0.3 parts by mass, with respect to 100 parts by mass of the inorganic filler (D). Setting the content of the flow adjuster (C) at a value equal to or greater than 0.005 parts by mass allows the flow adjuster (C) to express significant effects. On the other hand, setting the content of the flow adjuster (C) at a value greater than 0.5 parts by mass would make the effect achieved by the flow adjuster (C) saturated. This may make the thickness of the insulating layer 1 even more uniform.

### <Inorganic Filler (D)>

The inorganic filler (D) is an aggregate of particles with thermal conductivity. The inorganic filler (D) includes at least one filler selected from the group consisting of a magnesium oxide filler, an aluminum nitride filler, and an aluminum oxide filler. This may increase the thermal conductivity of the insulating layer 1 compared to a situation where the inorganic filler (D) includes none of these fillers. Optionally, the inorganic filler (D) may further include any of additional fillers (hereinafter collectively referred to as “third inorganic fillers (D3)”) other than the magnesium oxide filler, the aluminum nitride filler, and the aluminum oxide filler. Examples of the third inorganic fillers (D3) include, without limitation, molybdenum compound fillers, silica fillers, aluminum hydroxide fillers, magnesium hydroxide fillers, talc fillers, clay fillers, zinc oxide fillers, boron nitride fillers, and mica fillers.

The content of the inorganic filler (D) may be equal to or greater than 84% by mass and equal to or less than 97% by mass, is preferably equal to or greater than 85% by mass and equal to or less than 96% by mass, and more preferably equal to or greater than 87% by mass and equal to or less than 94% by mass, with respect to the entire mass of the resin composition. Note that the content of the inorganic filler (D) is the total content of the magnesium oxide filler, the aluminum nitride filler, and the aluminum oxide filler.

Setting the content of the inorganic filler (D) at a value equal to or greater than 84% by mass may increase the thermal conductivity of the insulating layer 1. On the other hand, setting the content of the inorganic filler (D) at a value equal to or less than 97% by mass may reduce the chances of causing a decrease in the flowability of the resin composition being molded or an excessive increase in the viscosity thereof.

The inorganic filler (D) preferably has, in a volume-based particle size distribution (frequency distribution) measured by the laser diffraction and scattering method, at least two peaks within a range in which the particle size is equal to or greater than 0.05 μm and equal to or less than 25 μm. This allows particles of the inorganic filler (D) to be closer to each other within the insulating layer 1.

In this case, the particle size distribution is measured by the laser diffraction and scattering method. The particle size distribution is expressed as a frequency distribution or a cumulative size distribution (cumulative distribution). As used herein, the “cumulative size distribution” refers to a cumulative undersize distribution.

The frequency distribution herein refers to a distribution expressed as a graph, of which the abscissa indicates the particle size, and the ordinate indicates the (volume-based) percentage of the amount of particles with each particle size to the entire amount of particles. The abscissa may also be expressed as a logarithmic scale.

On the other hand, the cumulative size distribution (cumulative undersize distribution) herein refers to a distribution expressed as a graph, of which the abscissa indicates the particle size, and the ordinate indicates the (volume-based) percentage of the amount of particles, of which the sizes are equal to or less than a certain particle size, to the entire amount of particles. The abscissa may also be expressed as a logarithmic scale.

The inorganic filler (D) preferably includes a first inorganic filler (D1) and a second inorganic filler (D2) having a mean particle size smaller than the mean particle size of the first inorganic filler (D1). This allows particles of the first inorganic filler (D1) to be brought into thermal contact with each other in the insulating layer 1 via particles of the second inorganic filler (D2). This may further increase the thermal conductivity of the insulating layer 1. As used herein, the “mean particle size” refers to a 50% size (D50 (median size)) of the cumulative size distribution (cumulative undersize distribution) described above.

The first inorganic filler (D1) preferably has a mean particle size greater than 1 μm and equal to or less than 25 μm, and more preferably has a mean particle size equal to or greater than 4 μm and equal to or less than 20 μm. On the other hand, the second inorganic filler (D2) preferably has a mean particle size equal to or greater than 0.05 μm and equal to or less than 1 μm, and more preferably has a mean particle size equal to or greater than 0.1 μm and equal to or less than 0.4 μm. This may further accelerate the thermal contact of the particles of the first inorganic filler (D1) in the insulating layer 1 via the particles of the second inorganic filler (D2). Consequently, this allows the thermal conductivity of the insulating layer 1 to be further increased.

The inorganic filler (D) has, in the volume-based particle size distribution (frequency distribution) measured by the laser diffraction and scattering method, at least one peak in a range where the particle size is greater than 1 μm and equal to or less than 25 μm and at least one peak in a range where the particle size is equal to or greater than 0.05 μm and equal to or less than 1 μm. This allows particles of the inorganic filler (D) to be even closer to each other within the insulating layer 1. Consequently, this allows the thermal conductivity of the insulating layer 1 to be further increased.

In the volume-based particle size distribution (cumulative size distribution) measured by the laser diffraction and scattering method, a cumulative proportion of particles, each having a particle size greater than 1 μm and equal to or less than 70 μm, is equal to or greater than 40% by volume and equal to or less than 80% by volume, and a cumulative proportion of particles, each having a particle size equal to or greater than 0.05 μm and equal to or less than 1 μm, is equal to or greater than 20% by volume and equal to or less than 60% by volume. This allows particles of the inorganic filler (D) to be even closer to each other within the insulating layer 1. Consequently, this allows the thermal conductivity of the insulating layer 1 to be further increased.

### <Other Additional Components>

Examples of the catalysts include, without limitation, imidazole compounds such as 2-ethyl-4-methylimidazole. Adding a catalyst to the resin composition allows for promoting the curing reaction of the resin composition being molded.

Examples of the flame retardants include, without limitation, phosphorus-based flame retardants, halogen-based flame retardants, and inorganic flame retardants. Adding a flame retardant to the resin composition may make the insulating layer 1 flame-retardant. Phosphorus-based flame retardants are preferred because phosphorus-based flame retardants are halogen-free.

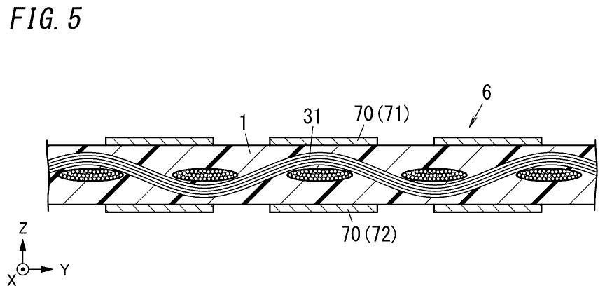

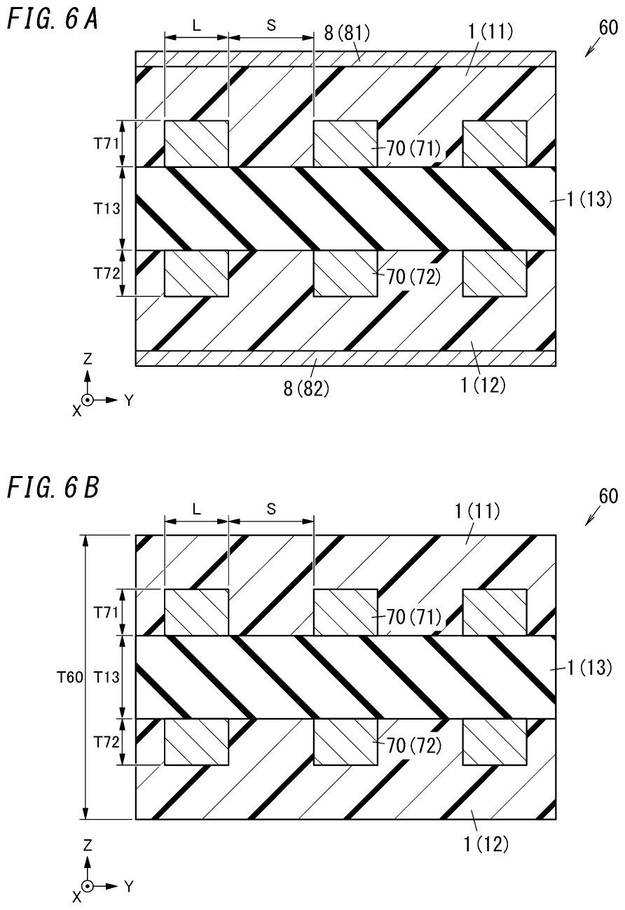

Examples of the coupling agent include, without limitation, silane coupling agents such as 8-glycidoxyoctyltrimethoxysilane. Adding a coupling agent to the resin composition may increase the degree of adhesion between the insulating layer 1 and the metal layer 51 (refer to FIGS. 4A and 4B) and the degree of adhesion between the insulating layer 1 and the conductor layer 70 (refer to FIGS. 5 and 6).

Examples of the dispersant include, without limitation, a wetting and dispersing agent. Adding a dispersant to the resin composition allows the inorganic filler (D) to be uniformly dispersed within the insulating layer 1.

Examples of the metal deactivator include, without limitation, hydrazide derivatives, oxalic acid derivatives, and salicylic acid derivatives. Adding a metal deactivator to the resin composition causes the metal deactivator to form a complex with active metal ions (e.g., copper ions) that accelerate oxidation deterioration. This may reduce the deterioration of the insulating layer 1.

Examples of the ion scavengers include, without limitation, hydrotalcite. Adding an ion scavenger to the resin composition allows the ion scavenger to trap ionic impurities. This reduces ion migration. Consequently, this ensures insulation reliability for the insulating layer 1.

(2) Film with Resin

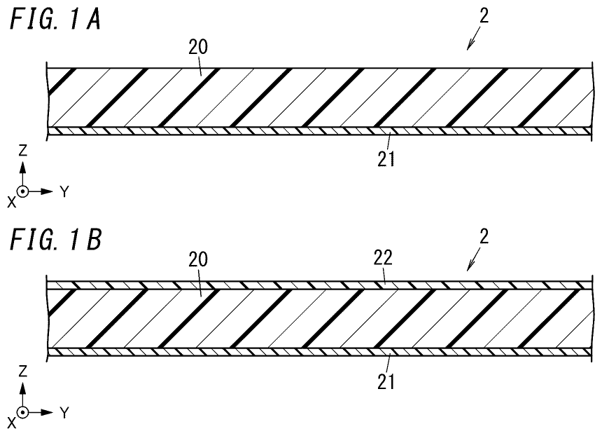

As shown in FIG. 1A, the film 2 with resin according to this embodiment is in the form of a film having a thickness in the Z-axis direction and extending in the X-axis direction and Y-axis direction. The film 2 with resin includes a resin layer 20 and a supporting film 21. The film 2 with resin may further include a protective film 22 as shown in FIG. 1B. The film 2 with resin may be used as a material for a buildup process.

### <Resin Layer>

The resin layer 20 is in the form of a film having a thickness in the Z-axis direction and extending in the X-axis direction and Y-axis direction. The resin layer 20 includes either the resin composition described above or a semi-cured product of the resin composition. The semi-cured product of the resin composition herein refers to a resin composition in an intermediate stage (Stage B) of the curing reaction. When heated, the resin layer 20 cures to turn into the insulating layer 1. The resin layer 20 may have, without limitation, a thickness equal to or greater than 50 μm and equal to or less than 200 μm, for example.

### <Supporting Film>

The supporting film 21 is attached to one surface (e.g., a surface facing the negative side of the Z-axis in FIGS. 1A and 1B) of the resin layer 20. In this manner, the supporting film 21 supports the resin layer 20 thereon. Having the supporting film 21 support the resin layer 20 in this way makes the resin layer 20 more easily handleable. Optionally, the supporting film 21 is peelable from the resin layer 20 as needed.

Examples of the supporting film 21 include, without limitation, a polyethylene terephthalate (PET) film, a polyimide film, a polyester film, a polyparabanic acid film, a polyether ether ketone film, a polyphenylene sulfide film, an aramid film, a polycarbonate film, and a polyarylate film.

### <Protective Film>

The protective film 22 is attached to the other surface (e.g., the surface facing the positive side of the Z-axis in FIG. 1B) of the resin layer 20. In this manner, the protective film 22 protects the resin layer 20. Making the protective film 22 protect the resin layer 20 reduces the chances of foreign particles being deposited on the resin layer 20. Optionally, the protective film 22, as well as the supporting film 21, is peelable from the resin layer 20 as needed.

Examples of the protective film 22 include, without limitation, a polyethylene terephthalate (PET) film, a polyolefin film, a polyester film, and a polymethylpentene film.

### (3) Prepreg

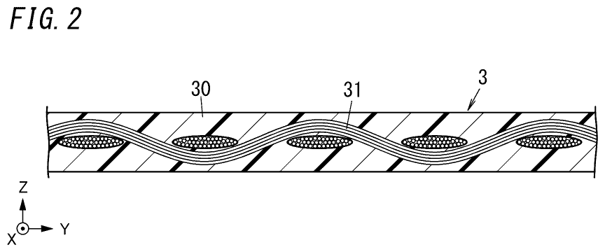

As shown in FIG. 2, the prepreg 3 according to this embodiment is in the form of a sheet having a thickness in the Z-axis direction and extending in the X-axis direction and Y-axis direction. The prepreg 3 includes a resin layer 30 and a fibrous base member 31. The prepreg 3, as well as the film 2 with resin, may be used as a material for a buildup process, for example. The prepreg 3 may have, without limitation, a thickness equal to or greater than 60 μm and equal to or less than 200 μm, for example.

### <Resin Layer>

The resin layer 30 includes either the resin composition described above or a semi-cured product of the resin composition. The resin composition is impregnated into the fibrous base member 31. When heated, the resin layer 30 cures to turn into the insulating layer 1.

### <Fibrous Base Member>

The fibrous base member 31 serves as a reinforcing member. The fibrous base member 31 is impregnated with the resin composition.

The fibrous base member 31 may be a piece of woven fabric or a piece of non-woven fabric. Examples of the fibrous base member 31 include, without limitation, glass cloth, aramid cloth, polyester cloth, glass non-woven fabric, aramid non-woven fabric, polyester non-woven fabric, pulp paper, and linter paper. The types of the glass cloth are preferably #7628, #1501, #2116, #1080, #1078, and #106.

(4) Sheet of Metal Foil with Resin

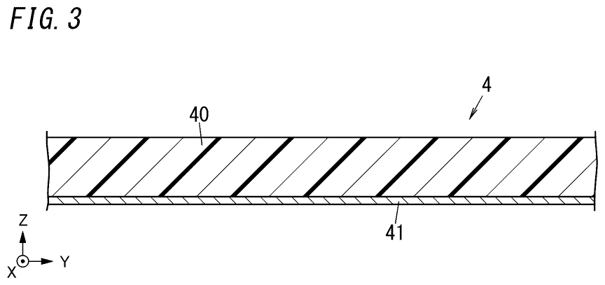

As shown in FIG. 3, the sheet of metal foil 4 with resin according to this embodiment is in the form of a sheet having a thickness in the Z-axis direction and extending in the X-axis direction and the Y-axis direction. The sheet of metal foil 4 with resin includes a resin layer 40 and a sheet of metal foil 41. The sheet of metal foil 4 with resin, as well as the film 2 with resin and the prepreg 3, may also be used as a material for a buildup process, for example.

### <Resin Layer>

The resin layer 40 includes either the resin composition described above or a semi-cured product of the resin composition. When heated, the resin layer 40 cures to turn into the insulating layer 1. The resin layer 40 may have, without limitation, a thickness equal to or greater than 60 μm and equal to or less than 200 μm.

### <Sheet of Metal Foil>

The sheet of metal foil 41 is bonded to the resin layer 40. In FIG. 3, the sheet of metal foil 41 is bonded to one surface of the resin layer 40 (i.e., a surface facing the negative side of the Z-axis). The sheet of metal foil 41 has its excessive portions removed by etching, for example, during the manufacturing process of the printed wiring board 6 to turn into a conductor layer 70.

Examples of the sheet of metal foil 41 include, without limitation, a sheet of copper foil (including a sheet of electrolytic copper foil and a sheet of rolled copper foil), a sheet of stainless steel foil, a sheet of nickel foil, and a sheet of nichrome foil. The sheet of metal foil 41 may have, without limitation, a thickness equal to or greater than 5 μm and equal to or less than 35 μm, for example.

### (5) Metal-Clad Laminate

As shown in FIGS. 4A and 4B, a metal-clad laminate 5 according to this embodiment is in the form of a plate having a thickness in the Z-axis direction and extending in the X-axis direction and Y-axis direction. The metal-clad laminate 5 includes an insulating layer 1 and at least one metal layer 51. Although the insulating layer 1 includes no fibrous base member 31 in FIG. 4A, the insulating layer 1 may include the fibrous base member 31 as shown in FIG. 4B. The metal-clad laminate 5 shown in FIGS. 4A and 4B is a double-sided metal-clad laminate. Alternatively, the metal-clad laminate 5 may also be a single-sided metal-clad laminate. The metal-clad laminate 5 may be used to manufacture a printed wiring board 6 (including a core member).

### <Insulating Layer>

The insulating layer 1 is a layer having electrical insulation properties. The insulating layer 1 includes either a cured product of the resin composition described above or a cured product of the prepreg 3 described above. The insulating layer 1 may include a plurality of fibrous base members 31. If the insulating layer 1 includes a plurality of fibrous base members 31, then the plurality of fibrous base members 31 are arranged one on top of another in the thickness direction (i.e., Z-axis direction). The insulating layer 1 may have, without limitation, a thickness equal to or greater than 50 μm and equal to or less than 200 μm, for example.

### <Metal Layer>

The metal layer 51 may be formed as the sheet of metal foil 41, a plating layer, or an evaporated film, whichever is appropriate. A metallic material for the metal layer 51 is not limited to any particular one but may be the same as the metallic material for the sheet of metal foil 41, for example. The metal layer 51 is bonded to the insulating layer 1. In FIGS. 4A and 4B, the metal layer 51 includes a first metal layer 511 and a second metal layer 512. The first metal layer 511 is bonded to one surface (i.e., the surface facing the positive side of the Z-axis) of the insulating layer 1, while the second metal layer 512 is bonded to the other surface (i.e., the surface facing the negative side of the Z-axis) of the insulating layer 1. Either the first metal layer 511 or the second metal layer 512 may be omitted. The metal layer 51 may have, without limitation, a thickness equal to or greater than 18 μm and equal to or less than 210 μm, for example.

### (6) Printed Wiring Board

As shown in FIG. 5, a printed wiring board 6 according to this embodiment is in the form of a plate having a thickness in the Z-axis direction and extending in the X-axis direction and Y-axis direction. The printed wiring board 6 includes an insulating layer 1 and at least one conductor layer 70. Although the insulating layer 1 includes a fibrous base member 31 in FIG. 5, the insulating layer 1 may include no fibrous base members 31. In FIG. 5, only one insulating layer 1 is provided. Alternatively, two or more insulating layers 1 may be provided. In FIG. 5, two conductor layers 70 are provided. Alternatively, only one conductor layer 70 or three or more conductor layers 70 may be provided. As can be seen, the “printed wiring board 6” as used herein also encompasses a multilayer printed wiring board (i.e., a printed wiring board with three or more conductor layers 70). Note that the printed wiring board 6 as used herein also encompasses the printed wiring boards 60 under test shown in FIGS. 6A and 6B. For example, the printed wiring board 60 under test shown in FIG. 6B includes three insulating layers 1 (namely, a first insulating layer 11, a second insulating layer 12, and a third insulating layer 13) and two conductor layers 70 (namely, a first conductor layer 71 and a second conductor layer 72).

### <Insulating Layer>

The insulating layer 1 includes either a cured product of the resin composition described above or a cured product of the prepreg 3 described above. A single insulating layer 1 may include a plurality of fibrous base members 31. If a single insulating layer 1 includes a plurality of fibrous base members 31, then the plurality of fibrous base members 31 are arranged one on top of another in the thickness direction (i.e., Z-axis direction). The insulating layer 1 may have, without limitation, a thickness equal to or greater than 50 μm and equal to or less than 1600 μm, for example.

### <Conductor Layer>

The conductor layer 70 includes: a signal layer for transmitting an electrical signal; a power supply layer for supplying electric power; and a ground layer for setting a ground potential. The conductor layer 70 is bonded to the insulating layer 1. The conductor layer 70 may be an external layer or an internal layer, whichever is appropriate. That is to say, the conductor layer 70 shown in FIG. 5 is provided outside the printed wiring board 6, and therefore, is an external layer. On the other hand, the conductor layers 70 shown in FIGS. 6A and 6B are provided inside the printed wiring board 60 under test, and therefore, are internal layers. The conductor layer 70 may have, without limitation, a thickness equal to or greater than 12 μm and equal to or less than 210 μm. The conductor layer 70 may have, without limitation, a conductor width L (refer to FIGS. 6A and 6B) equal to or greater than 100 μm and equal to or less than 800 μm, for example. The conductor layer 70 may have, without limitation, a conductor spacing S (refer to FIGS. 6A and 6B) equal to or greater than 100 μm and equal to or less than 800 μm, for example.

### <Advantages>

In this embodiment, the insulating layer 1 is a cured product of the resin composition described above. The resin composition contains an epoxy resin (A), a phenolic resin (B), a flow adjuster (C), and an inorganic filler (D).

In this embodiment, the flow adjuster (C) includes a polyether ester flow adjuster (C1) including no phosphorus atoms. The polyether ester flow adjuster (C1) including no phosphorus atoms mainly contributes to making the thickness of the insulating layer 1 uniform.

On the other hand, the inorganic filler (D) includes at least one filler selected from the group consisting of a magnesium oxide filler, an aluminum nitride filler, and an aluminum oxide filler. The content of the inorganic filler (D) is equal to or greater than 84% by mass and equal to or less than 97% by mass with respect to the entire mass of the resin composition. The inorganic filler (D) has, in a volume-based particle size distribution measured by a laser diffraction and scattering method, at least two peaks within a range in which a particle size is equal to or greater than 0.05 μm and equal to or less than 25 μm. The inorganic filler (D) mainly contributes to the thermal conductivity of the insulating layer 1.

As described above, if the resin composition contains the epoxy resin (A) and the phenolic resin (B), then the polyether ester flow adjuster (C1) including no phosphorus atoms achieves a particularly significant effect. That is to say, even if the resin composition includes the inorganic filler (D) at a high concentration but is a resin system including, in combination, the epoxy resin (A) and the phenolic resin (B), the polyether ester flow adjuster (C1) including no phosphorus atoms may ensure moderate flowability.

Consequently, this embodiment allows an insulating layer 1 to be formed with a high thermal conductivity and a uniform thickness.

### 3. Aspects

As can be seen from the foregoing description of exemplary embodiments, the present disclosure has the following aspects. In the following description, reference signs are added in parentheses to the respective constituent elements solely for the purpose of clarifying correspondence between the following aspects of the present disclosure and the exemplary embodiments described above.

A first aspect is a resin composition. The resin composition contains an epoxy resin (A), a phenolic resin (B), a flow adjuster (C), and an inorganic filler (D). The flow adjuster (C) includes a polyether ester flow adjuster (C1) including no phosphorus atoms. The inorganic filler (D) includes at least one filler selected from the group consisting of a magnesium oxide filler, an aluminum nitride filler, and an aluminum oxide filler. The content of the inorganic filler (D) is equal to or greater than 84% by mass and equal to or less than 97% by mass with respect to the entire mass of the resin composition. The inorganic filler (D) has, in a volume-based particle size distribution measured by a laser diffraction and scattering method, at least two peaks within a range in which a particle size is equal to or greater than 0.05 μm and equal to or less than 25 μm.

This aspect allows an insulating layer (1) to be formed with a high thermal conductivity and a uniform thickness.

A second aspect is a resin composition which may be implemented in conjunction with the first aspect. In the second aspect, the inorganic filler (D) includes: a first inorganic filler (D1); and a second inorganic filler (D2) having a mean particle size smaller than a mean particle size of the first inorganic filler (D1).

This aspect allows the thermal conductivity of the insulating layer (1) to be further increased.

A third aspect is a resin composition which may be implemented in conjunction with the second aspect. In the third aspect, the mean particle size of the first inorganic filler (D1) is greater than 1 μm and equal to or less than 25 μm, and the mean particle size of the second inorganic filler (D2) is equal to or greater than 0.05 μm and equal to or less than 1 μm.

This aspect allows the thermal conductivity of the insulating layer (1) to be further increased.

A fourth aspect is a resin composition which may be implemented in conjunction with any one of the first to third aspects. In the fourth aspect, the inorganic filler (D) has, in the volume-based particle size distribution measured by the laser diffraction and scattering method, at least one peak in a range where the particle size is greater than 1 μm and equal to or less than 25 μm and at least one peak in a range where the particle size is equal to or greater than 0.05 μm and equal to or less than 1 μm.

This aspect allows the thermal conductivity of the insulating layer (1) to be further increased.

A fifth aspect is a resin composition which may be implemented in conjunction with any one of the first to fourth aspects. In the fifth aspect, in the volume-based particle size distribution measured by the laser diffraction and scattering method, a cumulative proportion of particles, each having a particle size greater than 1 μm and equal to or less than 70 μm, is equal to or greater than 40% by volume and equal to or less than 80% by volume, and a cumulative proportion of particles, each having a particle size equal to or greater than 0.05 μm and equal to or less than 1 μm, is equal to or greater than 20% by volume and equal to or less than 60% by volume.

This aspect allows the thermal conductivity of the insulating layer (1) to be further increased.

A sixth aspect is a resin composition which may be implemented in conjunction with any one of the first to fifth aspects. In the sixth aspect, the flow adjuster (C) is liquid at 25° C. and non-ionic.

According to this aspect, the flow adjuster (C) in a liquid form at 25° C. increases the flexibility of a film material and makes the film material less easily crackable, thus improving the handleability of the film material. In addition, the non-ionic flow adjuster (C) is not ionized and has no electric charges, thus ensuring insulation reliability for the insulating layer (1).

A seventh aspect is a resin composition which may be implemented in conjunction with any one of the first to sixth aspects. In the seventh aspect, the polyether ester flow adjuster (C1) including no phosphorus atoms has, in a single molecule, a plurality of ether structures, a plurality of ester structures, and a plurality of carboxy groups.

This aspect may make the thickness of the insulating layer (1) even more uniform.

An eighth aspect is a resin composition which may be implemented in conjunction with any one of the first to seventh aspects. In the eighth aspect, the content of the flow adjuster (C) is equal to or greater than 0.005 parts by mass and equal to or less than 0.5 parts by mass with respect to 100 parts by mass of the inorganic filler (D).

This aspect may make the thickness of the insulating layer (1) even more uniform.

A ninth aspect is a film (2) with resin. The film (2) with resin includes: a resin layer (20) including either the resin composition according to any one of the first to eighth aspects or a semi-cured product of the resin composition; and a supporting film (21) supporting the resin layer (20).

This aspect allows an insulating layer (1) to be formed with a high thermal conductivity and a uniform thickness.

A tenth aspect is a prepreg (3). The prepreg (3) includes: a resin layer (30) including either the resin composition according to any one of the first to eighth aspects or a semi-cured product of the resin composition; and a fibrous base member (31) impregnated with the resin composition.

This aspect allows an insulating layer (1) to be formed with a high thermal conductivity and a uniform thickness.

An eleventh aspect is a sheet of metal foil (4) with resin. The sheet of metal foil (4) with resin includes: a resin layer (40) including either the resin composition according to any one of the first to eighth aspects or a semi-cured product of the resin composition; and a sheet of metal foil (41) bonded to the resin layer (40).

This aspect allows an insulating layer (1) to be formed with a high thermal conductivity and a uniform thickness.

A twelfth aspect is a metal-clad laminate (5). The metal-clad laminate (5) includes an insulating layer (1) including a cured product of the resin composition according to any one of the first to eighth aspects; and a metal layer (51) bonded to the insulating layer (1).

This aspect allows the insulating layer (1) to have a high thermal conductivity and a uniform thickness.

A thirteenth aspect is another metal-clad laminate (5). The metal-clad laminate (5) includes: an insulating layer (1) including a cured product of the prepreg (3) according to the tenth aspect; and a metal layer (51) bonded to the insulating layer (1).

This aspect allows the insulating layer (1) to have a high thermal conductivity and a uniform thickness.

A fourteenth aspect is a printed wiring board (6). The printed wiring board (6) includes an insulating layer (1) including a cured product of the resin composition according to any one of the first to eighth aspects; and a conductor layer (70) bonded to the insulating layer (1).

This aspect allows the insulating layer (1) to have a high thermal conductivity and a uniform thickness.

A fifteenth aspect is another printed wiring board (6). The printed wiring board (6) includes an insulating layer (1) including a cured product of the prepreg (3) according to the tenth aspect; and a conductor layer (70) bonded to the insulating layer (1).

This aspect allows the insulating layer (1) to have a high thermal conductivity and a uniform thickness.

### EXAMPLES

Next, specific examples of the present disclosure will be described. Note that the examples to be described below are only examples of the present disclosure and should not be construed as limiting.

### 1. Examples and Comparative Examples

### (1) Materials

The following materials were used to make resin compositions according to respective examples and comparative examples:

### <Epoxy Resin (A)>

Epoxy resin 1: trisphenolmethane epoxy resin, product name “EPPN502H,” manufactured by Nippon Kayaku Co., Ltd., having an epoxy equivalent of 158 to 178 g/eq; and
Epoxy resin 2: trisphenolmethane epoxy resin, product name “HP-7250,” manufactured by DIC Corporation, having an epoxy equivalent of 150 to 180 g/eq.

### <Phenolic Resin (B)>

Biphenyl-aralkyl phenolic resin, product name “MEHC-7403H,” manufactured by UBE Corporation, having a hydroxyl group equivalent of 132 g/eq.

### <Flow Adjuster (C)>

### <<Polyether Ester Flow Adjuster (C1) Including No Phosphorus Atoms>>

Polyether ester type 1: product name “Disparlon 3350EF,” manufactured by Kusumoto Chemicals, Ltd.;
Polyether ester type 2: product name “Disparlon 3600N,” manufactured by Kusumoto Chemicals, Ltd.; and
Polyether ester type 3: product name “Disparlon 3800,” manufactured by Kusumoto Chemicals, Ltd.

### <<Other Flow Adjusters (C)>>

Polyamide type: product name “Disparlon 3900EF,” manufactured by Kusumoto Chemicals, Ltd.; and
Polyether phosphate ester type: product name “Disparlon 3500,” manufactured by Kusumoto Chemicals, Ltd.

### <Inorganic Filler (D)>

### <<First Inorganic Filler (D1)>>

Aluminum oxide filler 1: product name “AZ10-20,” manufactured by NIPPON STEEL Chemical & Material Co., Ltd.;
Magnesium oxide filler: product name “RF-10CS,” manufactured by Ube Material Industries, Ltd.;
Aluminum nitride filler: product name “HF-10c,” manufactured by Tokuyama Corporation; and
Calcium carbonate filler: product name “MS-PS,” manufactured by Konoshima Chemical Co., Ltd.,

### <<Second Inorganic Filler (D2)>>

Aluminum oxide filler 2: product name “AO-502,” manufactured by ADMATECHS, having a specific surface area of 6.5 to 9.0 m²/g).

### <<Third Inorganic Filler (D3)>>

Molybdenum compound filler, product name “KG-501,” manufactured by J. M. Huber Corporation.

### <Others>

### <<Curing Agent>>

Dicyandiamide (Dicy).

### <<Catalyst>>

2-ethyl-4-methylimidazole, product name “2E4MZ,”, manufactured by Shikoku Chemicals Corporation.

### <<Flame Retardant>>

Phosphazene-based flame retardant (non-halogen flame retardant), product name “FP-100,” manufactured by FUSHIMI Pharmaceutical Co., Ltd.

### <<Coupling Agent>>

Silane coupling agent (8-glycidoxyoctyltrimethoxysilane), product name “KBM-4803,” manufactured by Shin-Etsu Chemical Co., Ltd.

### <<Dispersant>>

Wetting and dispersing agent, product name “BYK-W903,” manufactured by BYK-Chemie.

### <<Metal Deactivator>>

Hydrazide-based, product name “CDA-10,” manufactured by ADEKA Corporation.

### <<Ion Scavenger>>

Hydrotalcite-based inorganic ion scavenger, product name “IXEPLAS-A1,” manufactured by Toagosei Co., Ltd.

### (2) Resin Composition

Resin compositions according to respective examples and comparative examples were manufactured by mixing respective materials in the proportions (where the unit is parts by mass) shown in the following Tables 1 and 2:

TABLE 1
(unit: parts by mass)

| | | | Examples | | | | | | | | |
|---|---|---|---|---|---|---|---|---|---|---|---|
| | | | 1 | 2 | 3 | 4 | 5 | 6 | 7 | 8 | 9 |
| Epoxy resin (A) | Epoxy resin 1 | | 20.0 | 20.0 | 20.0 | 20.0 | 20.0 | 20.0 | 20.0 | 20.0 | 20.0 |
| | Epoxy resin 2 | | 40.0 | 40.0 | 40.0 | 40.0 | 40.0 | 40.0 | 40.0 | 40.0 | 40.0 |
| Phenolic resin (B) | | | 40.0 | 40.0 | 40.0 | 40.0 | 40.0 | 40.0 | 40.0 | 40.0 | 40.0 |
| Other curing agents | | | 0 | 0 | 0 | 0 | 0 | 0 | 0 | 0 | 0 |
| Catalyst | | | 0.5 | 0.5 | 0.5 | 0.5 | 0.5 | 0.5 | 0.5 | 0.5 | 0.5 |
| Flame retardant | | | 10.0 | 10.0 | 10.0 | 10.0 | 10.0 | 10.0 | 10.0 | 10.0 | 10.0 |
| Coupling agent | | | 15.6 | 17.8 | 17.8 | 17.8 | 17.8 | 17.8 | 18.0 | 16.1 | 10.8 |
| Dispersant | | | 10.9 | 12.5 | 12.5 | 12.5 | 12.5 | 12.5 | 12.6 | 11.3 | 7.5 |
| Inorganic | First | Aluminum oxide filler 1 | 900.0 | 1028.0 | 1028.0 | 1028.0 | 1028.0 | 1028.0 | 780.0 | 0 | 0 |
| Fillers (D) | Inorganic | Magnesium oxide filler | 0 | 0 | 0 | 0 | 0 | 0 | 260.0 | 0 | 0 |
| | Filler (D1) | Aluminum nitride filler | 0 | 0 | 0 | 0 | 0 | 0 | 0 | 975.0 | 650.0 |
| | | Calcium carbonate filler | 0 | 0 | 0 | 0 | 0 | 0 | 0 | 0 | 0 |
| | Second | Aluminum oxide filler 2 | 600.0 | 685.3 | 685.3 | 685.3 | 685.3 | 685.3 | 693.3 | 566.0 | 377.3 |
| | Inorganic | | | | | | | | | | |
| | Filler (D2) | | | | | | | | | | |
| | Third | Molybdenum compound | 63.0 | 70.0 | 70.0 | 70.0 | 70.0 | 70.0 | 71.0 | 70.0 | 50.0 |
| | Inorganic | Filler | | | | | | | | | |
| | Filler (D3) | | | | | | | | | | |

| Heavy metal deactivator | Hydrazide-based | 1.0 | 1.0 | 1.0 | 1.0 | 1.0 | 1.0 | 1.0 | 1.0 | 1.0 |
|---|---|---|---|---|---|---|---|---|---|---|
| Ion scavenger | Hydrotalcite-based | 17.0 | 20.0 | 20.0 | 20.0 | 20.0 | 20.0 | 19.5 | 18.0 | 12.0 |
| Flow adjusters (C) | Polyether ester type 1 (C1) | 1.2 | 1.2 | 0.8 | 0.4 | 0 | 0 | 1.2 | 1.2 | 1.2 |
| | Polyether ester type 2 (C1) | 0 | 0 | 0 | 0 | 1.2 | 0 | 0 | 0 | 0 |
| | Polyether ester type 3 (C1) | 0 | 0 | 0 | 0 | 0 | 1.2 | 0 | 0 | 0 |
| | Polyamide type | 0 | 0 | 0 | 0 | 0 | 0 | 0 | 0 | 0 |
| | Polyether phosphate ester type | 0 | 0 | 0 | 0 | 0 | 0 | 0 | 0 | 0 |

TABLE 2
(unit: parts by mass)

| | | | Comparative examples | | | | | |
|---|---|---|---|---|---|---|---|---|
| | | | 1 | 2 | 3 | 4 | 5 | 6 |
| Epoxy resin (A) | Epoxy resin 1 | | 20.0 | 20.0 | 20.0 | 30.0 | 20.0 | 20.0 |
| | Epoxy resin 2 | | 40.0 | 40.0 | 40.0 | 65.0 | 40.0 | 40.0 |
| Phenolic resin (B) | | | 40.0 | 40.0 | 40.0 | 0 | 40.0 | 40.0 |
| Other curing agents | | | 0 | 0 | 0 | 5.0 | 0 | 0 |
| Catalyst | | | 0.5 | 0.5 | 0.5 | 0.5 | 0.5 | 0.5 |
| Flame retardant | | | 10.0 | 10.0 | 10.0 | 10.0 | 10.0 | 10.0 |
| Coupling agent | | | 17.8 | 17.8 | 17.8 | 18.3 | 9.9 | 10.1 |
| Dispersant | | | 12.5 | 12.5 | 12.5 | 12.8 | 6.9 | 7.1 |
| Inorganic | First | Aluminum oxide filler 1 | 1028.0 | 1028.0 | 1028.0 | 1055.0 | 0 | 1025.0 |
| Fillers (D) | Inorganic | Magnesium oxide filler | 0 | 0 | 0 | 0 | 0 | 0 |
| | Filler (D1) | Aluminum nitride filler | 0 | 0 | 0 | 0 | 0 | 0 |
| | | Calcium carbonate filler | 0 | 0 | 0 | 0 | 400.0 | 0 |
| | Second | Aluminum oxide filler 2 | 685.3 | 685.3 | 685.3 | 703.3 | 542.3 | 0 |
| | Inorganic | | | | | | | |
| | Filler (D2) | | | | | | | |
| | Third | Molybdenum compound | 70.0 | 70.0 | 70.0 | 72.0 | 47.0 | 11.0 |
| | Inorganic | Filler | | | | | | |
| | Filler (D3) | | | | | | | |

| Heavy metal deactivator | Hydrazide-based | 1.0 | 1.0 | 1.0 | 1.0 | 1.0 | 1.0 |
|---|---|---|---|---|---|---|---|
| Ion scavenger | Hydrotalcite-based | 20.0 | 20.0 | 20.0 | 20.0 | 11.0 | 12.0 |
| Flow adjusters (C) | Polyether ester type 1 (C1) | 0 | 0 | 0 | 0 | 0 | 1.2 |
| | Polyether ester type 2 (C1) | 0 | 0 | 0 | 1.2 | 0 | 0 |
| | Polyether ester type 3 (C1) | 0 | 0 | 0 | 0 | 0 | 0 |
| | Polyamide type | 0 | 1.2 | 0 | 0 | 0 | 0 |
| | Polyether phosphate ester type | 0 | 0 | 1.2 | 0 | 0 | 0 |

D50 (50% particle size of the cumulative size distribution) and D99 (99% particle size of the cumulative size distribution) of the first inorganic filler (D1) and the second inorganic filler (D2) are shown in the following Table 3:

TABLE 3

(unit: μm)

| | | D50 | D99 |
|---|---|---|---|
| First inorganic | Aluminum oxide filler 1 | 8-10 | <40 |
| fillers (D1) | Magnesium oxide filler | 5-10 | <50 |
| | Aluminum nitride filler | 5-10 | <40 |
| | Calcium carbonate filler | 10-13 | <50 |
| Second inorganic | Aluminum oxide filler 2 | 0.2-0.3 | <5 |
| filler (D2) | | | |

(3) Film with Resin

The above-described materials were mixed together to prepare compounds having the chemical makeups shown in Tables 1 and 2. Each of those compounds was either dissolved or dispersed in methyl ethyl ketone as a solvent and stirred up in a planetary mixer, thereby preparing varnish including the resin composition according to a corresponding one of the respective examples and comparative examples. The varnish was applied onto a supporting film and then dried at 150° C. for 2 to 5 minutes, thereby manufacturing a film with resin (including a resin layer with a thickness of 150 μm and dimensions of 255 mm×340 mm) according to each of the examples and comparative examples.

### (4) Printed Wiring Board Under Test

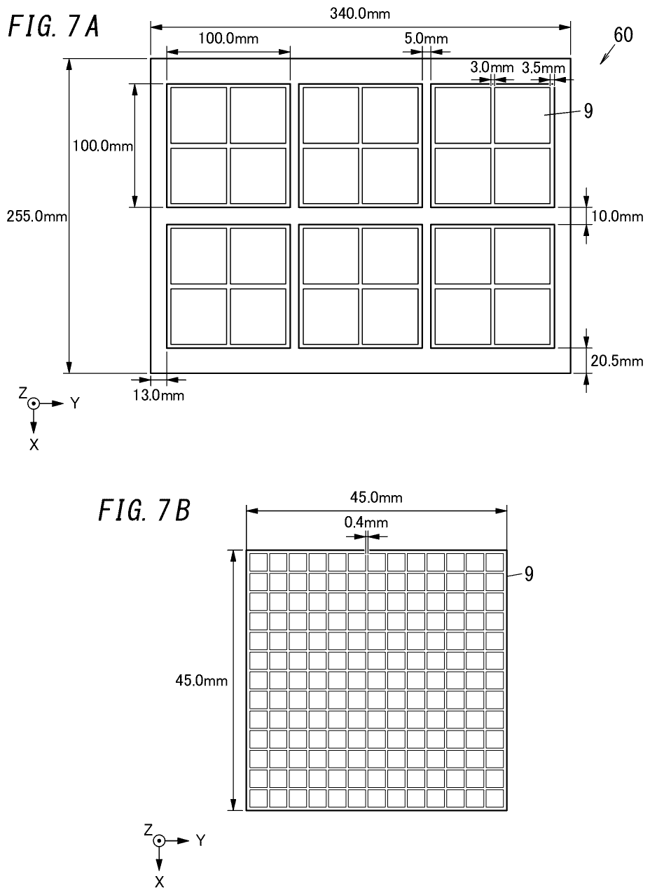

A double-sided copper clad laminate (a highly refractory halogen-free multilayer board material, product name “R-1566S,” manufactured by Panasonic Corporation, having a thickness of 400 μm, copper foil having a thickness of 105 μm and dimensions of 255 mm×340 mm) was provided. The sheets of copper foil on both sides of the double-sided copper clad laminate were subjected to an etching process, thereby forming a conductor layer (dummy pattern) with a residual copper rate of 80% and obtaining a core member. FIG. 7A shows a conductor layer (dummy pattern) of a core member when viewed in an XY plane. This dummy pattern is made up of a plurality of pattern elements 9. FIG. 7B shows a single pattern element 9 when viewed in an XY plane. The dummy pattern includes four pattern elements in the X-axis direction multiplied by six pattern elements in the Y-axis direction (i.e., twenty-four pattern elements in total).

Next, a sheet of surface-treated electrolytic copper foil (product name “CF-T8G-UN-18,” manufactured by Fukuda Metal Foil & Powder Co., Ltd., having a nominal thickness of 18 μm and dimensions of 550 mm×700 mm) was stacked, via the resin layer of the film with resin (from which the supporting film had been peeled off), on each surface of the core member and heated under pressure under the condition including a temperature of 200° C., a pressure of 3 MPa, and a duration of 60 minutes), thereby manufacturing a printed wiring board 60 under test (refer to FIG. 6A). Thereafter, the sheets of copper foil were removed by etching from both sides of the printed wiring board 60 under test.

### 2. Evaluation

### (1) Thermal Conductivity

An insulating layer was obtained by heating and thereby curing the resin layer of the film with resin. The thermal conductivity of the insulating layer was measured by laser flash method defined by the JIS R 1611 standard. The results are shown in the following Tables 4 and 5.

### (2) Thickness of Insulating Layer

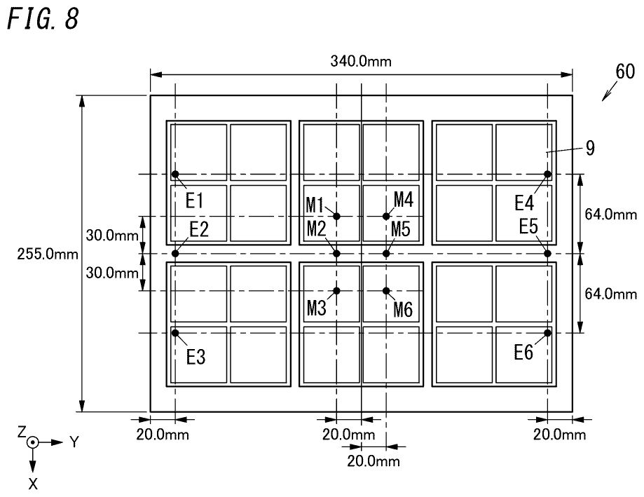

As for the printed wiring board 60 under test, the thickness of the insulating layer thereof was measured. Respective points (twelve points in total, namely, M1-M6 and E1-E6) where the thickness of the printed wiring board under test were measured when viewed in an XY plane are shown in FIG. 8. Specifically, respective thicknesses in the Z-axis direction were measured with a micrometer at the six points M1-M6 in a central area of the printed wiring board 60 under test and the six points E1-E6 at end portions of the printed wiring board 60 under test. Then, the thickness of the insulating layer at each of these twelve points was calculated (by (T60−T13−T71−T72)/2 in FIG. 6B). The results (average values) are shown in the following Tables 4 and 5:

TABLE 4

| | | | Examples | | | | | | | | |
|---|---|---|---|---|---|---|---|---|---|---|---|
| | | Unit | 1 | 2 | 3 | 4 | 5 | 6 | 7 | 8 | 9 |
| Ion scavenger | Content | mass % | 1.0 | 1.0 | 1.0 | 1.0 | 1.0 | 1.0 | 1.0 | 1.0 | 1.0 |
| Metal deactivator | Content | phr | 1.0 | 1.0 | 1.0 | 1.0 | 1.0 | 1.0 | 1.0 | 1.0 | 1.0 |
| Inorganic | (D1)/(D2) ratio by volume | — | 60/40 | 60/40 | 60/40 | 60/40 | 60/40 | 60/40 | 60/40 | 67/33 | 67/33 |
| Filler (D) | Content | mass % | 87 | 88 | 88 | 88 | 88 | 88 | 88 | 87 | 84 |
| Peak points of | First inorganic filler (D1) | μm | 0.17 | 0.17 | 0.17 | 0.17 | 0.17 | 0.17 | 0.17 | 0.17 | 0.17 |
| Particle size | Second inorganic filler (D2) | μm | 9.30 | 9.30 | 9.30 | 9.30 | 9.30 | 9.30 | 9.30 | 9.50 | 9.50 |
| Distribution | | | | | | | | | 7.5 | | |
| Thermal conductivity | — | W/m · K | 3.6 | 4 | 4 | 4 | 4 | 4 | 4.5 | 5.5 | 3.9 |
| Thickness of | Thickness in central area | μm | 134 | 135 | 130 | 134 | 135 | 132 | 132 | 134 | 130 |
| insulating layer | Thickness in end portions | μm | 129 | 130 | 123 | 125 | 121 | 119 | 126 | 124 | 121 |
| | Difference in thickness | μm | 5 | 5 | 7 | 9 | 14 | 13 | 6 | 10 | 9 |
| | between central area and | | | | | | | | | | |
| | end portions | | | | | | | | | | |

TABLE 5

| | | | Comparative examples | | | | | |
|---|---|---|---|---|---|---|---|---|
| | | Unit | 1 | 2 | 3 | 4 | 5 | 6 |
| Ion scavenger | Content | mass % | 1.0 | 1.0 | 1.0 | 1.0 | 1.0 | 1.0 |
| Metal deactivator | Content | phr | 1.0 | 1.0 | 1.0 | 1.0 | 1.0 | 1.0 |
| Inorganic | (D1)/(D2) ratio by volume | — | 60/40 | 60/40 | 60/40 | 60/40 | 49/51 | 100/0 |
| Filler (D) | Content | mass % | 88 | 88 | 88 | 88 | 83 | 87 |
| Peak points of | First inorganic filler (D1) | μm | 0.17 | 0.17 | 0.17 | 0.17 | 0.17 | — |
| Particle size | Second inorganic filler (D2) | μm | 9.30 | 9.30 | 9.30 | 9.30 | 11.50 | 9.30 |
| Distribution | | | | | | | | |
| Thermal conductivity | — | W/m · K | 4 | 4 | 4 | 4 | 2.4 | Could |
| Thickness of | Thickness in central area | μm | 132 | 133 | 130 | 128 | 129 | not |
| insulating layer | Thickness in end portions | μm | 79 | 85 | 80 | 86 | 79 | be |
| | Difference in thickness | μm | 53 | 48 | 50 | 42 | 50 | formed |
| | between central area and | | | | | | | |
| | end portions | | | | | | | |

### REFERENCE SIGNS LIST

1 Insulating Layer
2 Film with Resin
20 Resin Layer
21 Supporting Film
3 Prepreg
30 Resin Layer
31 Fibrous Base Member
4 Sheet of Metal Foil with Resin
40 Resin Layer
41 Sheet of Metal Foil
5 Metal-Clad Laminate
51 Metal Layer
6 Printed Wiring Board
70 Conductor Layer

1. A resin composition containing an epoxy resin (A), a phenolic resin (B), a flow adjuster (C), and an inorganic filler (D),
the flow adjuster (C) including a polyether ester flow adjuster (C1) including no phosphorus atoms,
the inorganic filler (D) including at least one filler selected from the group consisting of a magnesium oxide filler, an aluminum nitride filler, and an aluminum oxide filler,
content of the inorganic filler (D) being equal to or greater than 84% by mass and equal to or less than 97% by mass with respect to entire mass of the resin composition, and
the inorganic filler (D) having, in a volume-based particle size distribution measured by a laser diffraction and scattering method, at least two peaks within a range in which a particle size is equal to or greater than 0.05 m and equal to or less than 25 m.

2. The resin composition of claim 1, wherein
the inorganic filler (D) includes: a first inorganic filler (D1); and a second inorganic filler (D2) having a mean particle size smaller than a mean particle size of the first inorganic filler (D1).

3. The resin composition of claim 2, wherein
the mean particle size of the first inorganic filler (D1) is greater than 1 m and equal to or less than 25 μm, and
the mean particle size of the second inorganic filler (D2) is equal to or greater than 0.05 μm and equal to or less than 1 μm.

4. The resin composition of claim 1, wherein
the inorganic filler (D) has, in the volume-based particle size distribution measured by the laser diffraction and scattering method, at least one peak in a range where the particle size is greater than 1 μm and equal to or less than 25 μm and at least one peak in a range where the particle size is equal to or greater than 0.05 μm and equal to or less than 1 μm.

5. The resin composition of claim 1, wherein
in the volume-based particle size distribution measured by the laser diffraction and scattering method, a cumulative proportion of particles, each having a particle size greater than 1 μm and equal to or less than 70 μm, is equal to or greater than 40% by volume and equal to or less than 80% by volume, and a cumulative proportion of particles, each having a particle size equal to or greater than 0.05 μm and equal to or less than 1 μm, is equal to or greater than 20% by volume and equal to or less than 60% by volume.

6. The resin composition of claim 1, wherein
the flow adjuster (C) is liquid at 25° C. and non-ionic.

7. The resin composition of claim 1, wherein
the polyether ester flow adjuster (C1) including no phosphorus atoms has, in a single molecule, a plurality of ether structures, a plurality of ester structures, and a plurality of carboxy groups.

8. The resin composition of claim 1, wherein
content of the flow adjuster (C) is equal to or greater than 0.005 parts by mass and equal to or less than 0.5 parts by mass with respect to 100 parts by mass of the inorganic filler (D).

9. A film with resin, comprising:
a resin layer including either the resin composition of claim 1 or a semi-cured product of the resin composition; and
a supporting film supporting the resin layer.

10. A prepreg comprising:
a resin layer including either the resin composition of claim 1 or a semi-cured product of the resin composition; and
a fibrous base member impregnated with the resin composition.

11. A sheet of metal foil with resin, comprising:
a resin layer including either the resin composition of claim 1 or a semi-cured product of the resin composition; and
a sheet of metal foil bonded to the resin layer.

12. A metal-clad laminate comprising:
an insulating layer including a cured product of the resin composition of claim 1; and
a metal layer bonded to the insulating layer.

13. A metal-clad laminate comprising:
an insulating layer including a cured product of the prepreg of claim 10; and
a metal layer bonded to the insulating layer.

14. A printed wiring board comprising:
an insulating layer including a cured product of the resin composition of claim 1; and
a conductor layer bonded to the insulating layer.

15. A printed wiring board comprising:
an insulating layer including a cured product of the prepreg of claim 10; and
a conductor layer bonded to the insulating layer.
